(19) United States
(12) Patent Application Publication
(10) Pub. No.: US 2025/0044450 A1
(43) Pub. Date: Feb. 6, 2025

(54) A NON-LIVE WIRE MOUNTED SENSOR MODULE AND METHOD FOR MOUNTING THEREOF

(71) Applicant: INFRAVISION HOLDING PTY LTD, Coolum Beach Queensland (AU)

(72) Inventors: Cameron Van Der Berg, Camperdown (AU); Daniel Van Der Berg, Camperdown (AU)

(21) Appl. No.: 18/717,258

(22) PCT Filed: Dec. 9, 2022
(86) PCT No.: PCT/AU2022/051482

§ 371 Date: Jun. 6, 2024

(30) Foreign Application Priority Data
Dec. 9, 2021 (AU) 2021903983

(51) Int. Cl. G01S 17/88; G01D 21/02; G01J 1/42; G01K 7/16; G01S 17/08; G01W 1/02

(52) U.S. Cl. CPC G01S 17/88; G01D 21/02; G01J 1/42; G01K 7/16; G01S 17/08; G01W 1/02; G01J 2001/4266

(57) ABSTRACT

There is provided a non-live wire mounted sensor module in the form of an earth wire mounted sensor module including a housing including a mounting means adapted to mount the module to an earth power line wire. The sensor module includes a processing unit in the form of a microprocessor and a physical sensor unit both supported by the housing. The sensor module includes a power supply coupled to the microprocessor and the physical sensor unit for supplying power to the microprocessor and physical sensor unit. The microprocessor is housed within the housing and also coupled to a communications unit also housed within the housing for facilitating external communication of output of the physical sensor unit.

### TECHNICAL FIELD

The present disclosure relates to mounted sensor devices. The present disclosure has applications in the field of power line mounted sensor devices and methods for mounting sensor device to a non-live power line wire.

While some embodiments will be described herein with particular reference to that application, it will be appreciated that the invention is not limited to such a field of use, and is applicable in broader contexts.

### BACKGROUND

Any discussion of the background art throughout the specification should in no way be considered as an admission that such art is widely known or forms part of common general knowledge in the field.

The mounting of sensors for monitoring various conditions in outdoor locations is commonplace. Powerline towers and lines are used as supports for mounting such sensors as they are an existing structural support that often provides a reasonably desirable position for the sensors to provide meaningful data.

Further, the sensors mounted to the powerlines are often in place to sense conditions that are pertinent to the functioning of the powerline, looking at measurables such as dynamic line rating (DLR), line sag and clearance of lines to objects and the ground, and weather conditions. However, for sensors used to calculate DLR in particular, there is a very strong preference to have these mounted to the active line, which necessitates downtime as the power supply to the active line must be turned off in order to safely mount a DLR sensors on the active line. As those powerlines provide electricity supply to various infrastructure, this downtime is undesirable to both the power supplier and the consumer.

In respect of sensors for line sag and clearance of lines to objects and the ground, the measurement samples taken by known sensors are done at certain times. Therefore, should a line be moving due to windy weather conditions, the measure of clearance may not be taken at a point where the line is closest to an object, thus not providing accurate information on how close the line actually gets to an object.

Another commonly used sensors for measuring line sag and clearance involves the use of video cameras. Such sensors record video and an object detection process is applied to the raw footage to identify and measure distances to objects and the ground. However, there are issues with object recognition in particular to reliable and accurately identifying the ground. Further, the accuracy is largely governed by the quality of camera used, in particular the pixels density, that is, the field of divided by the number of pixels.

Other known technologies used for measuring line sag and clearance include sonar, radar, microwave and infrared sensors. However, the accuracy of these technologies is hampered by the relatively wide beam width where even the more narrow width beams will result in a significant potential margin of error.

Existing sensors for mounting to powerlines also require manual installation which not only can be inefficient but presents potential safety issues to the installer given the height of the installation and the fact that it is mounted to a high voltage powerline. Further, manual mounting will generally occur at a position on the lower powerline or relatively low position on a support powerline tower. Mounting sensors for monitoring weather conditions at a lower point will negatively impact the accuracy of readings taken.

### SUMMARY

It is an object of the present invention to overcome or ameliorate at least one of the disadvantages of the prior art, or to provide a useful alternative.

In accordance with a first aspect of the present invention there is provided a non-live wire mounted sensor module including:
a housing including a mounting means adapted to mount the module to a non-live power line wire;
a power supply a physical sensor unit supported by the housing, wherein the physical sensor unit includes at least one of the group including:
   a conductor temperature sensor;
   a weather station;
   a line sag detection sensor;
   an object proximity sensor; and
   a line movement sensor; and
a communications unit housed within the housing for facilitating external communication of output of the at least one physical sensor unit.

In an embodiment, the physical sensor unit includes a plurality of the group including:
the conductor temperature sensor;
the weather station;
the line sag detection sensor;
the object proximity sensor; and
the line movement sensor.

In an embodiment, the power supply includes a solar panel mounted externally on the housing.

In an embodiment, the power supply includes at least one battery disposed within the housing. In an embodiment, the at least one battery is rechargeable.

In an embodiment, the weather station includes one or more of: a temperature sensor; a solar radiation sensor; a wind speed sensor; and a wind direction sensor.

In an embodiment, the conductor temperature sensor includes an infrared sensor.

In another embodiment, the physical sensor unit includes an earth wire temperature sensor.

In an embodiment, the line sag detection sensor includes a LiDAR sensor.

In an embodiment, the object proximity sensor includes a LiDAR sensor.

In an embodiment, the line movement sensor includes one or more of: a gyroscope; an accelerometer; a global positioning system (GPS) sensor; and a LiDAR sensor.

In an embodiment, the physical sensor unit includes an integrated sensor including the functionality of both the line sag detection sensor and the object proximity sensor.

In an embodiment, the physical sensor unit is mounted externally to the housing.

In an embodiment, the physical sensor unit is mounted within the housing.

In an embodiment, the physical sensor unit is mounted both externally and within the housing.

In an embodiment, the mounting means includes at least one clamp mechanism.

In an embodiment, the mounting means includes a pair of clamp mechanisms.

In an embodiment, the clamp mechanism includes a raptor clamp.

In accordance with a second aspect of the present invention there is provided a method for mounting a sensor module on a non-live power line wire using an unmanned aerial vehicle (UAV), the method including the steps of:
providing a non-live wire mounted sensor module of any one of the preceding claims;
releasably attaching the sensor module to the UAV;
from a launch point, controlling the UAV to move it to a sensor release point such that the mounting means is positioned for mounting to the non-live wire;
controlling the UAV to initiate mounting to the non-live wire; and
controlling the UAV to release the sensor module once mounted to the non-live wire.

In accordance with a third aspect of the present invention there is provided a system for sensing one or more physical measurements, the system including:
at least one non-live wire mounted sensor module of the third aspect;
a communications arrangement for facilitating digital communications with a server; and
a communications gateway node for facilitating digital communications between the at least one sensor module and the communications arrangement.

In an embodiment, the system for sensing one or more physical measurements includes a plurality of sensor modules and the respective communications units of the plurality of sensor modules create a mesh network for communicating the plurality of sensor modules with the communications gateway node.

Other aspects of the present disclosure are also provided.

Reference throughout this specification to “one embodiment”, “some embodiments” or “an embodiment” means that a particular feature, structure or characteristic described in connection with the embodiment is included in at least one embodiment of the present invention. Thus, appearances of the phrases “in one embodiment”, “in some embodiments” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

In the claims below and the description herein, any one of the terms comprising, comprised of or which comprises is an open term that means including at least the elements/features that follow, but not excluding others. Thus, the term comprising, when used in the claims, should not be interpreted as being limitative to the means or elements or steps listed thereafter. For example, the scope of the expression a device comprising A and B should not be limited to devices consisting only of elements A and B. Any one of the terms including or which includes or that includes as used herein is also an open term that also means including at least the elements/features that follow the term, but not excluding others. Thus, including is synonymous with and means comprising.

### BRIEF DESCRIPTION OF THE DRAWINGS

One or more embodiments of the present disclosure will now be described by way of specific example(s) with reference to the accompanying drawings, in which:

FIG. 1A is a schematic block representation of an earth wire mounted sensor module according to an embodiment of the invention;

FIG. 1B is a schematic block representation of an earth wire mounted sensor module according to an embodiment of the invention;

FIGS. 2 to 6, and 8 are each perspective views of different embodiments of the earth wire mounted sensor module of either of FIG. 1A or FIG. 1B;

FIG. 7A is a top perspective view of an embodiment of the earth wire mounted sensor module of either of FIG. 1A or FIG. 1B;

FIG. 7B is a bottom perspective view of the earth wire mounted sensor module of FIG. 8A;

FIG. 9 is a profile view of an embodiment of the earth wire mounted sensor module of either of FIG. 1A or FIG. 1B shown mounted to an earth wire in use;

FIG. 10 is a schematic representation of an example of a communication system for facilitating communication with the earth wire mounted sensor module of either of FIG. 1A or FIG. 1B;

FIG. 11 is a schematic block representation of a gateway communications node for facilitating external communication of the earth wire mounted sensor module of either of FIG. 1A or FIG. 1B; and

FIGS. 12 and 13 are each perspective views of different embodiments of the gateway communications node of FIG. 11.

### DETAILED DESCRIPTION

Where applicable, steps or features in the accompanying drawings that have the same reference numerals are to be considered to have the same function(s) or operation(s), unless the contrary intention is expressed or implied.

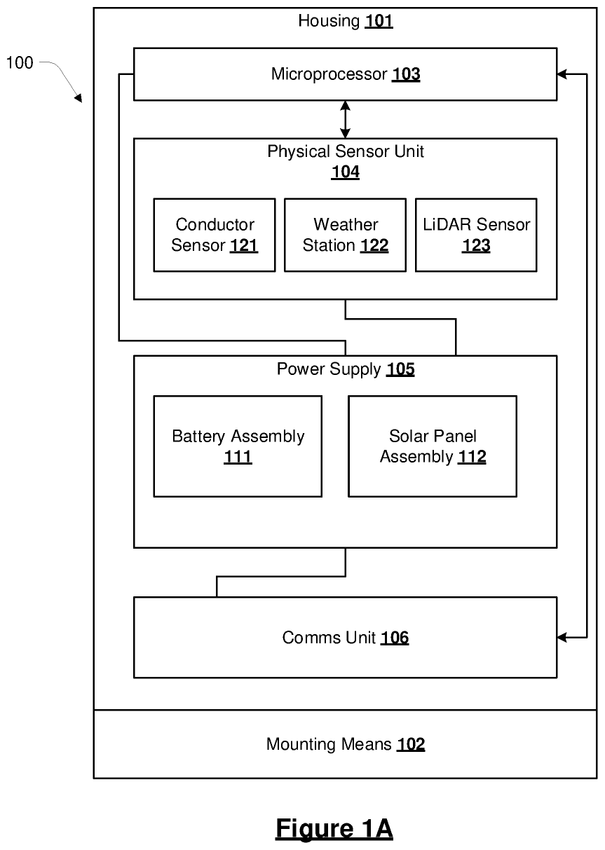

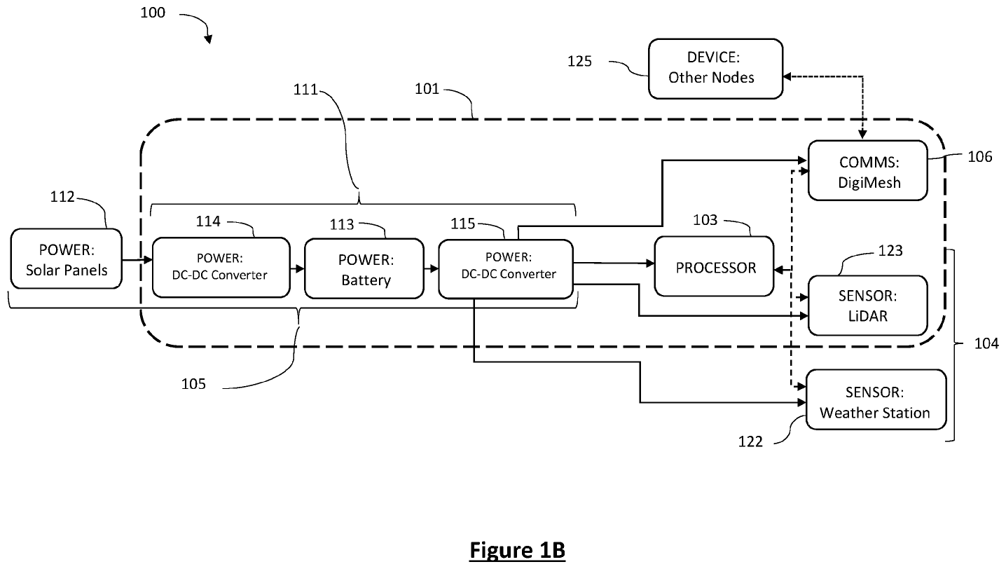

Referring to initially to FIGS. 1A and 1B there is provided a non-live wire mounted sensor module in the form of an earth wire mounted sensor module 100 including a housing 101 including a mounting means 102 adapted to mount the module to an earth power line wire. Sensor module 100 includes a processing unit in the form of a microprocessor 103 and a physical sensor unit 104 supported by housing 101, that is either mounted externally on housing 101 or mounted within housing 101. Physical sensor unit 104 is a term used to collectively describe one or more of:
a conductor temperature sensor including an infrared conductor sensor 121;
a weather station 122 including one or more of: a temperature sensor (which in some embodiments includes infrared conductor sensor 121); a solar radiation sensor; a humidity sensor; a wind speed sensor; a wind direction sensor; a smoke detector; and a fire detector;
a line sag detection sensor including a LiDAR sensor;
an object proximity sensor including a LiDAR sensor; and
a line movement sensor including one or more of: a gyroscope; an accelerometer; a global positioning system (GPS) sensor; and a LiDAR sensor.

The individual sensors of physical sensor unit 104 will vary between embodiments, but includes at least of one the above sensors. For example: in FIG. 1A, physical sensor unit 104 includes conductor sensor 121, weather station 122 and a LiDAR sensor 123; and in FIG. 1B, physical sensor unit 104 includes weather station 122 which may take the form of a known suitable Weather Station, and LiDAR sensor 123 which may take the form of a known suitable LiDAR sensor. It will be appreciated that in other embodiments, sensors are used other than what is stated above. For example, in other embodiments, LiDAR sensor 123 is one of: Jenoptik LDM71, Lightware SF30D, AllInBest.com 25IQ-NDTT-W DRL, or WorldSensing LS-G6-LAS-TI L90. In some embodiments, physical sensor unit 104 includes an earth wire temperature sensor for providing an understanding of the sag of the earth wire.

Sensor module 100 includes a power supply 105 coupled to microprocessor 103 and physical sensor unit 104 for supplying power to microprocessor 103 and physical sensor unit 104. Microprocessor 103 is housed within housing 101 and also coupled to a communications unit 106 also housed within housing 101 for facilitating external communication of output of the physical sensor unit(s) 104. In the embodiment of FIG. 1B, microprocessor 103 takes the form of a STM32H7 processor.

Power supply 105 includes a rechargeable battery in the form of a lithium-ion battery assembly 111 mounted within housing 101 and a solar panel assembly 112 mounted externally on housing 101. It will be appreciated that solar panel assembly 112 is used to re-charge battery assembly 111. Referring specifically to FIG. 1B, battery assembly 111 includes: a battery 113; a first DC-DC converter 114 upstream of battery 113 and downstream of solar panel assembly 112; and a second DC-DC converter 115 downstream of battery 113. It will be appreciated that power supply 105 is such that solar panel assembly 112 and battery assembly 111 are able to power microprocessor 103 and physical sensor unit 104 in varying weather conditions, that is, in weather conditions that are not conducive to providing great amounts of solar energy and therefore solar panel assembly 112 cannot be heavily relied upon for providing power.

Housing 101 is formed from a rigid weather-proof plastic polymer that is configured to house at least some of the electronic components of sensor module 100 in order to protect those components from weather such as precipitation and dust. In some embodiments, housing 101 is completely waterproof. Housing 101 is preferably of a size and material as small and light as practical to contain and support the relevant components of senor module 100 so as not to impact the dynamic response or add overdue fatigue to the earth wire upon which sensor module 100 is mounted. The specific physical form of housing 101 will vary in various embodiments, a number of which will be described further below.

Referring specifically to FIG. 1A and as noted above, the infrared conductor sensor 121 at least measures conductor temperature, weather station 122 measures weather conditions (including air temperature, wind speed and direction, solar radiation, humidity, smoke and fire) and LiDAR sensor 123 for providing sag detection and objection proximity sensing.

As will be appreciated by those skilled in the art, infrared conductor sensor 121 for measuring conductor temperature includes an infrared beam laser for emitting an infrared energy beam that is aimed at a conductor wire for sensing the temperature of that conductor wire. It will be appreciated that there is generally multiple conductor wires that can be measured.

Weather station 122, as noted above, includes one or more sensor components for measuring various aspects of localised weather conditions. In preferred embodiments, weather station 122 includes wind direction and speed sensors as well as the temperature sensor. Wind speed in particular is a major component of the calculation of DLR (about 55% of the DLR is based on wind speed). This is due to more wind providing more cooling for the conductor wire and lower ambient temperature resulting in more current to be running in the conductor wire for the same sag profile than if the conductor was in higher ambient temperatures. This in turn affects the sag profile of the conductor wire, where lower temperature will reduce sag. The opposite will be the case for lower winds. Weather station 122 is generally mounted to the exterior of housing 101, or mounted within housing 101 such that it has external access in order to properly measure the weather conditions. Weather station 122 also provides data relative to risk management of transmission line easements and wild fire detection. This includes sensors detecting the presence of smoke and heat relating to bushfires, for example, smoke detectors and an infrared camera.

The use of both infrared conductor sensor 121 and weather station 122 also allows the measurement in real-time of the temperature of the nearest conductor. It will be appreciated that the conductor temperature is deduced by line sag (measured by LiDAR sensor 123) taking into account the ambient temperature and the wind speed (measured by the weather station 122) which provides information of environmental conditions, which are accounted for in order to create the conductor temperature measurement.

The LiDAR sensor for measuring line sag is also generally mounted to the exterior of housing 101, or mounted within housing 101 such that it has external access in order to properly measure the weather conditions. This LiDAR sensor will be aimed towards the ground and will periodically initiate a distance scan to measure the distance from the LiDAR sensor to the ground. The measurements of distance from the ground will also be used as part of the monitoring of movement of the earth wire.

The LiDAR sensor for measuring object proximity is also generally mounted to the exterior of housing 101, or mounted within housing 101 such that it has external access in order to properly measure the weather conditions. This LiDAR sensor will be aimed towards a known object, such as vegetation, and will periodically initiate a distance scan to measure the distance from the LiDAR sensor to the object.

In the embodiment of FIGS. 1A and 1B, the LiDAR sensor for measuring line sag and the LiDAR sensor for measuring object proximity are actually a single integrated LiDAR sensor, LiDAR sensor 123, for measuring both line sag and object proximity. In yet other embodiments, LiDAR sensor 123 is able to adjust where it is aimed, this aiming being controlled by microprocessor 103. This aim adjustment will be based on whether the present distance scan is for taking a distance measurement to the ground, the nearest objects (such as conductor wire) or to vegetation.

LiDAR sensor 123 will include a lens that will require cleaning due to environmental conditions. Such cleaning can be from one or more of the following:
Using a passive lens hood to minimise rain and then dust building up on lens;
Using an active cleaning system including a cleaning fluid being applied to the lens and a wiper mechanism wiping the fluid from the lens;
Using active ultrasonic cleaning, perhaps in combination with a solvent along with the ultrasonic vibration; and
Using a hydrophobic lens coating.

Movement of the earth wire, including line blow out (horizontal movement) and line galloping (vertical movement), will be monitored by a gyroscope, an accelerometer, and a GPS sensor, which are collectively referred to as an inertial measurement unit (IMU). All components of the IMU are preferably housed within housing 101 and are able to provide constant feedback on earth wire movement. The measurements of each of LiDAR sensor 123, gyroscope, accelerometer, and GPS sensor are collectively inputted into microprocessor 103 to quantitatively measure the displacement of the earth wire.

In addition to distance to ground and objects such as vegetation, in some embodiments LiDAR sensor 123 is also configured to measure the distance from the earth wire to the conductor wires, and also the distance between the conductor wires by providing three dimensional coordinated measurements (i.e. x, y and z) from the earth wire to the conductor wires.

As noted above, certain individual sensors of physical sensor unit 104 (such as conductor sensor 121, weather station 122 and LiDAR sensor 123) require external access in order to accurately obtain measurements and they are generally mounted externally on housing 101. In some of those embodiments, housing 101 will have an access panel for allowing external access for physical sensor units 104. For example, for LiDAR sensor 123, housing 101 includes a translucent window through which LiDAR sensor 123 can be externally accessed. However, certain other individual components of physical sensor unit 104 (such as the gyroscope, the accelerometer and the GPS) are housed within housing 101 as they are able to properly function within the housing.

Microprocessor 103 is housed within housing 101 and receives sensor information from physical sensor unit 104. Further, it also provides instructions to some components of physical sensor unit 104, such as conductor sensor 121 and LiDAR sensor 123, in order to activate them to initiate respective scan measurements. The received sensor information is processed by microprocessor 103 into more efficiently transmissible packet data and the packet data is communicated externally via communications unit 106.

Communications unit 106 includes a mesh network comms unit (such as a DigiMesh unit or the like) to create a mesh network where multiple sensor modules 100 (collectively illustrated in FIG. 1B as reference 125) are in communication with each other either directly or indirectly within that mesh network. In some embodiments, communications unit 106 also or alternatively includes satellite and/or 4G communications capabilities for facilitating digital communications to an external server via the cloud. More specifically, communications unit 106 enables microprocessor 103 to communicate sensor information either one or more adjacent sensor modules via the mesh network or to the cloud via a communications satellite and/or 4G communications (this will be explained further below).

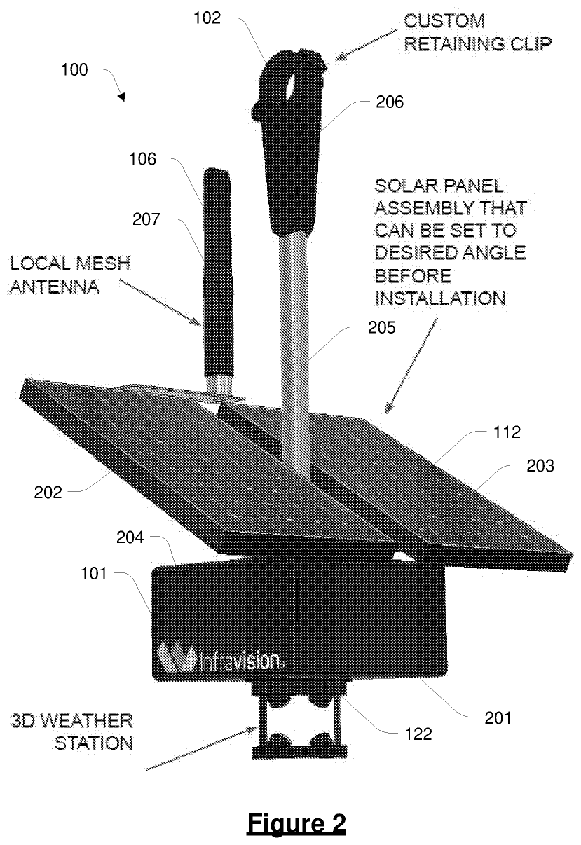

Referring to FIGS. 2, 3 and 4, there is illustrated embodiments of sensor module 100 where physical sensor unit 104 includes only weather station 122.

Referring to FIG. 2, housing 101 takes the form of a rectangular prism where weather station 122 is mounted externally to a bottom surface 201 of housing 101. Solar panel assembly 112 includes a pair of solar panels 202 and 203 mounted on a top surface 204 of housing 101 by way of a bracket (not shown). Further, mounting means 102 includes a vertically mounted shaft 205 mounted at one end to top surface 204 and at the other end to a clamping mechanism in the form of a retaining clip 206 that is adapted to attach to an earth wire. Communications unit 106 includes a mesh network antenna 207.

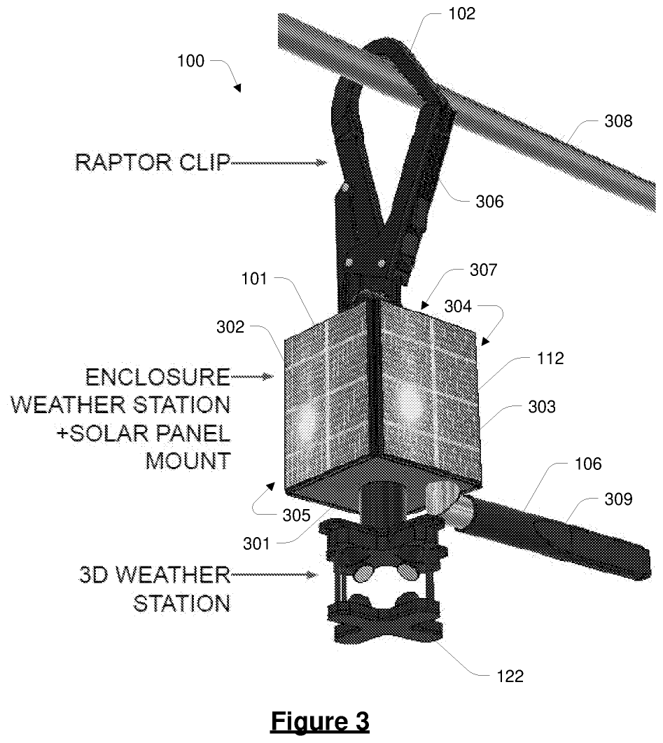

Referring to FIG. 3, housing 101 takes the form of a rectangular prism where weather station 122 is mounted externally to a bottom surface 301 of housing 101. Solar panel assembly 112 includes four solar panels 302, 303, 304 and 305 each mounted on a different side of housing 101. Further, mounting means 102 includes a clamping mechanism in the form of a raptor clamp 306 mounted at one end to a top surface 307 of housing 101 and adapted to attach to an earth wire 308. Communications unit 106 includes a mesh network antenna 309.

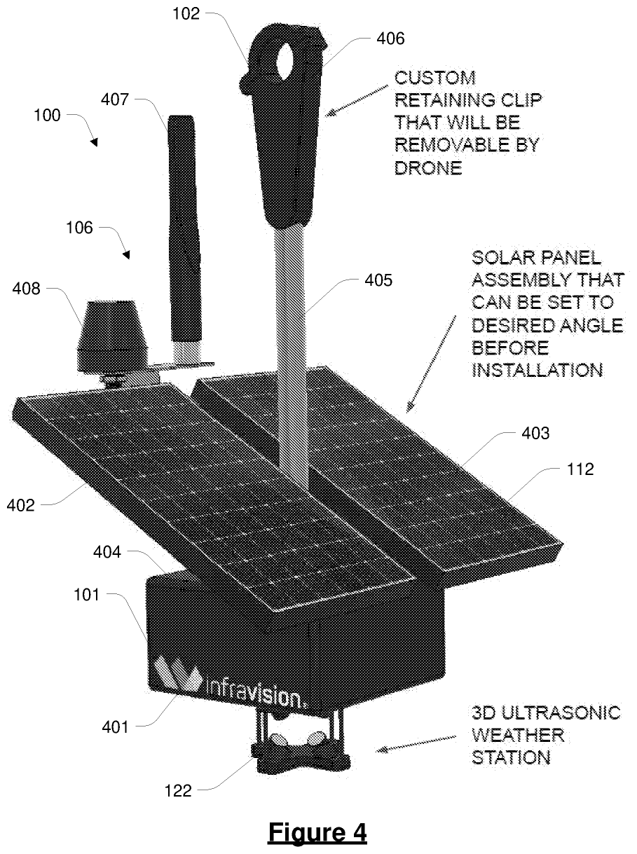

Referring to FIG. 4, housing 101 takes the form of a rectangular prism where weather station 122 is mounted externally to a bottom surface 401 of housing 101. Solar panel assembly 112 includes a pair of solar panels 402 and 403 mounted on a top surface 404 of housing 101 by way of a bracket (not shown). Further, mounting means 102 includes a vertically mounted shaft 405 mounted at one end to top surface 404 and at the other end to a clamping mechanism in the form of a retaining clip 406 that is adapted to attach to an earth wire. Communications unit 106 includes a mesh network antenna 407 and an additional satellite antenna 408.

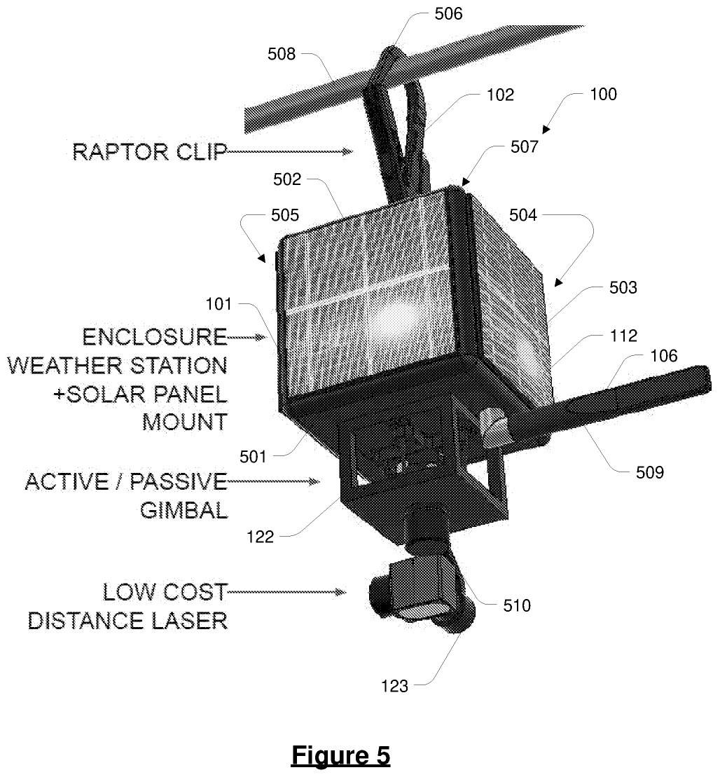

Referring to FIG. 5, there is illustrated an embodiment of sensor module 100 where physical sensor unit 104 includes weather station 122 and LiDAR sensor 123. Housing 101 takes the form of a rectangular prism where weather station 122 is mounted externally to a bottom surface 501 of housing 101 and LiDAR sensor 123 is mounted to weather station 122 by way of a gimbal 510. Solar panel assembly 112 includes four solar panels 502, 503, 504 and 505 each mounted on a different side of housing 101. Further, mounting means 102 includes a clamping mechanism in the form of a raptor clamp 506 mounted at one end to a top surface 507 of housing 101 and adapted to attach to an earth wire 508. Communications unit 106 includes a mesh network antenna 509.

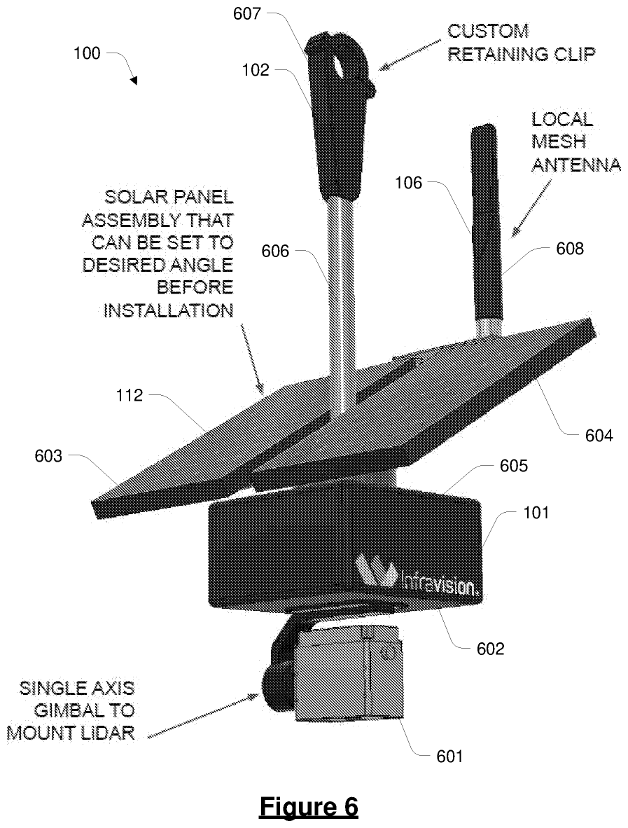

Referring to FIG. 6, there is illustrated embodiments of sensor module 100 without physical sensor unit 104 but being adapted to have physical sensor unit 104 in the form of only LiDAR sensor 123 mounted to it. Housing 101 takes the form of a rectangular prism where a LiDAR sensor gimbal mount 601 is mounted externally to a bottom surface 602 of housing 101. Solar panel assembly 112 includes a pair of solar panels 603 and 604 mounted on a top surface 605 of housing 101 by way of a bracket (not shown). Further, mounting means 102 includes a vertically mounted shaft 606 mounted at one end to top surface 605 and at the other end to a clamping mechanism in the form of a retaining clip 607 that is adapted to attach to an earth wire. Communications unit 106 includes a mesh network antenna 608.

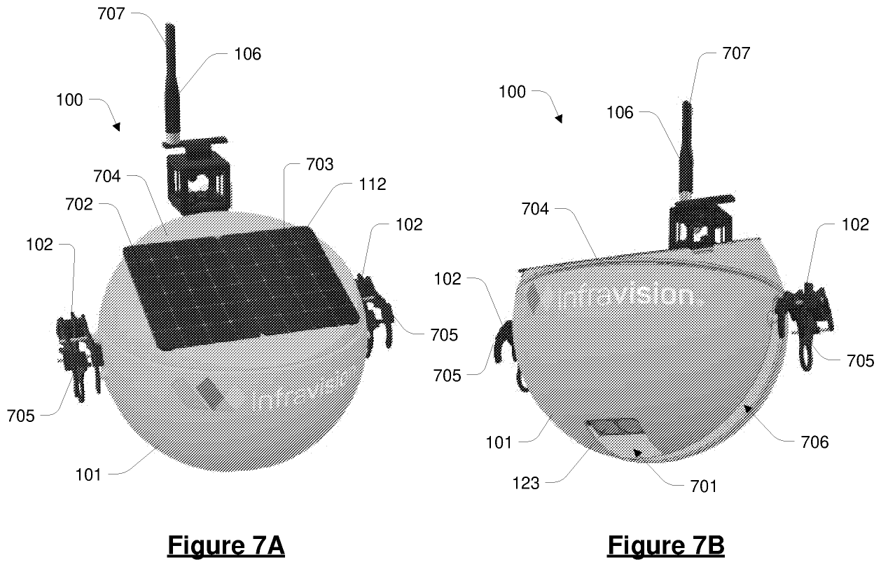

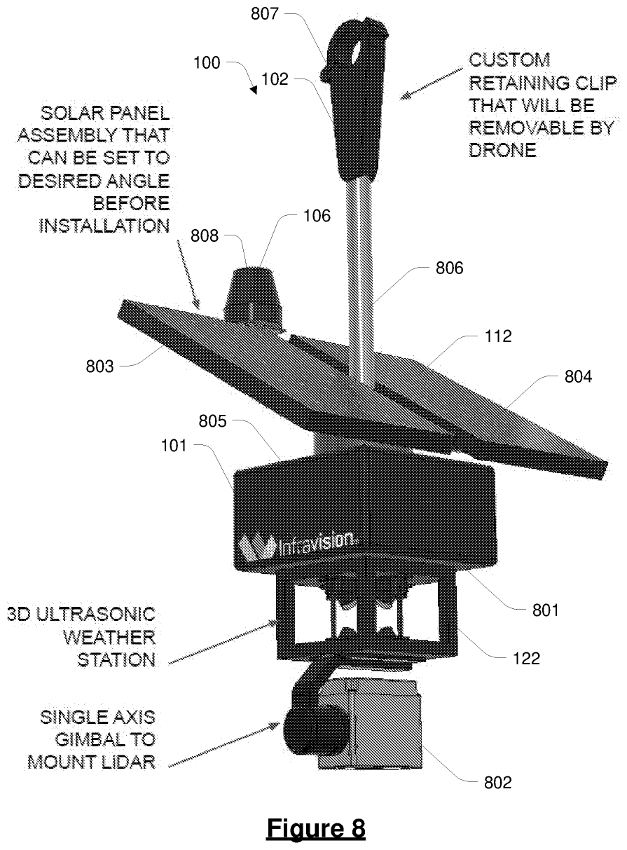

Referring to FIGS. 7A and 7B, there is illustrated an embodiment of sensor module 100 where physical sensor unit 104 includes only LiDAR sensor 123. Housing 101 takes the form of a power line marker ball where LiDAR sensor 123 is housed within housing 101. Housing 101 has a window 701 where LiDAR sensor 123 can be externally accessed. Solar panel assembly 112 includes a pair of solar panels 702 and 703 mounted on a top surface 704 of housing 101. Further, mounting means 102 includes a groove formation 706 and a pair of clamping mechanisms in the form of a pair of retaining clips 705 disposed on opposing sides of housing 101 at opposite ends of formation 706 such that formation 706 is configured to receive the earth wire when sensor module 100 is positioned and dropped on the earth wire and clips 705 are each adapted to attach to the earth wire. Communications unit 106 includes a mesh network antenna 707.

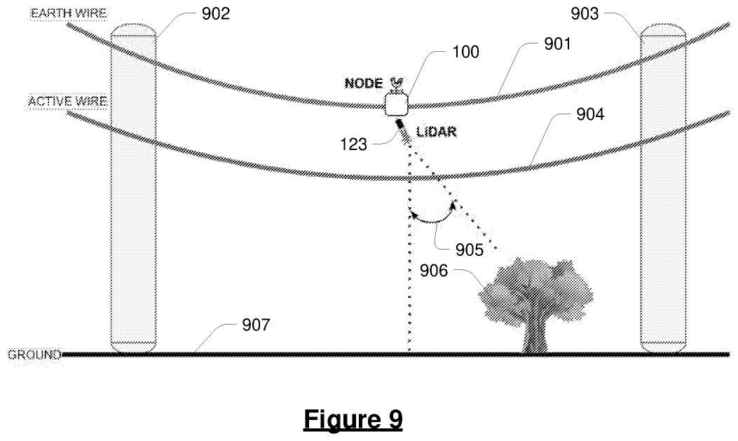

Referring to FIG. 8, there is illustrated an embodiment of sensor module 100 where physical sensor unit 104 includes only weather station 122. In addition, this embodiment is adapted to have LiDAR sensor 123 mounted to it. Housing 101 takes the form of a rectangular prism where weather station 122 is mounted externally to a bottom surface 801 of housing 101. Further, a LiDAR sensor gimbal mount 802 is mounted to the bottom surface of weather station 122. Solar panel assembly 112 includes pair of solar panels 803 and 804 mounted on a top surface 805 of housing 101. Further, mounting means 102 includes a vertically mounted shaft 806 mounted at one end to top surface 805 and at the other end to a clamping mechanism in the form of a retaining clip 807 that is adapted to attach to an earth wire. Communications unit 106 includes a satellite antenna 808.

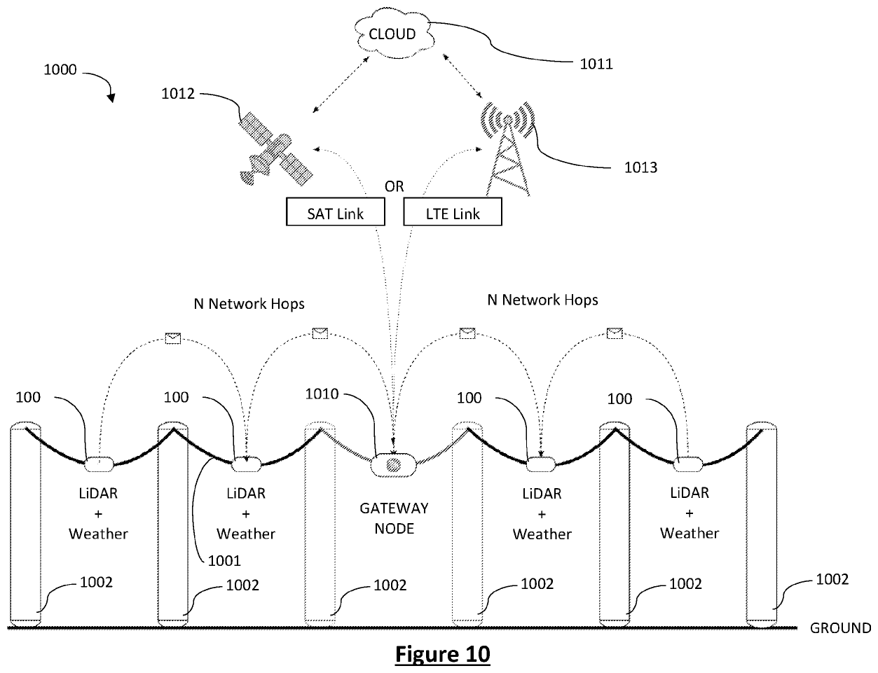

Referring to FIG. 9, there is shown sensor module 100 mounted to an earth wire 901 that is supported by a pair of powerline towers 902 and 903. Powerline towers 902 and 903 also support an active wire 904. Sensor module is shown with LiDAR sensor 123 in use directing a beam 905 towards an object in the form of vegetation 906 and a ground area 907. LiDAR sensor 123 is illustrated as initiating a distance scan to measure the distance from the LiDAR sensor to vegetation 906 and ground area 907.

Sensor module 100 is configured to be installable on earth wire 100 by an unmanned aerial vehicle (UAV). Sensor module 100 is firstly releasably attached to the UAV at a launch point and the UAV is controlled move the UAV to a desired sensor release point along earth wire 100. The release point will be preferably be a critical span point, that being the lowest sag point to ground 907 which is generally equidistant from the support powerline towers, or at a point closest to known object such as vegetation 906. This is because upon movement of earth wire 901, these are the points most likely to come into contact with vegetation 906 or ground 907.

Once at the sensor release point, mounting means 102 of sensor module 100 is positioned for initiating mounting to earth wire 901. For the embodiments where mounting means includes a retaining clip (that is, the embodiments of FIGS. 2, 4, 6 and 8) and for the embodiments where mounting means includes a raptor clamp (that is, the embodiments of FIGS. 3 and 5), the UAV will move sensor module 100 such that the respective clip will be attached to earth wire 901 be a lever of the respective clip moving upon contact with earth wire 901 to allow earth wire 901 to be positioned within the clip which locks earth wire 901 in place (the earth wire having been locked in place is actually illustrated in FIGS. 3 and 5 with respect to the raptor clamp, but the same will apply to the embodiments with the retaining clip).

For the embodiment of sensor module 100 of FIGS. 7A and 7B, once at the sensor release point, sensor module 100 is positioned by the UAV for initiating mounting such that formation 706 is above earth wire 901. UAV then lowers sensor module 100 such that formation 706 receives earth wire 901 and the lowering motion continues until earth wire 901 engages retaining clips 705 such that a lever of each of retaining clips 705 moves upon contact with earth wire 901 to allow earth wire 901 to be positioned within the retaining clips 705 which lock earth wire 901 in place.

Once sensor module 100 is mounted to earth wire 901, the installation is complete. The UAV is then controlled to release sensor module 100 and move to a desired location such as the launch point.

It will be appreciate that on standard power line arrangements, earth wires are disposed above the active wires. Therefore, mounting a weather station on the higher earth wire over the lower active wire (or a lower position on a support powerline tower) provides a better means for weather detection due to the height and there being less object interference at that height.

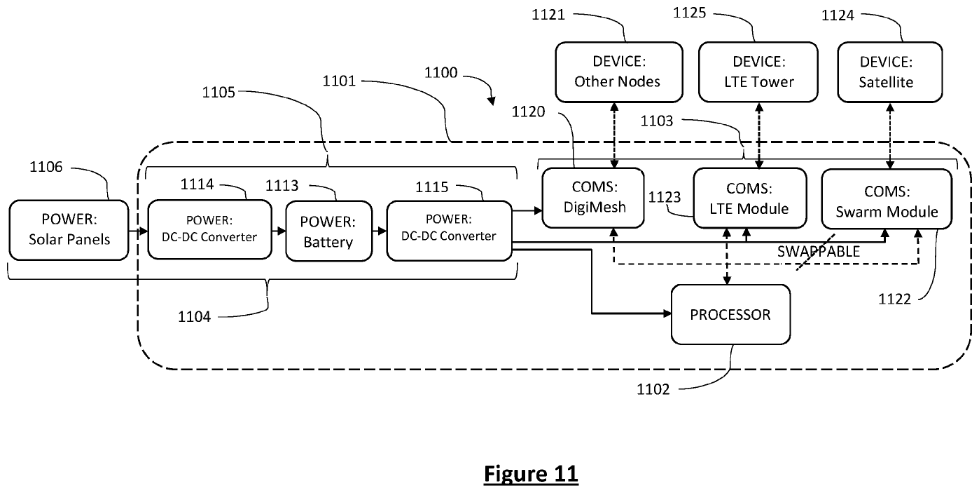

Referring now to FIG. 10, there is illustrated a communication system 1000 for facilitating external communication to and from a plurality of identical sensor modules 100, each having mesh network communications capabilities only. Each sensor module 100 is mounted to an earth wire 1001 that is supported by a plurality of powerline towers 1002. System 1000 further includes a gateway node 1010 also mounted to earth wire 1001. Gateway node 1010 will be described in more detail below, but generally speaking, gateway node 1010 is a standalone node that includes both mesh network communications capabilities to facilitating digital communications with the plurality of sensor modules 100 and also satellite and/or 4G communications capabilities for communicating to the cloud 1011 respectively via a communications arrangement such as a communications satellite 1012 and/or a Long Term Evolution (LTE) tower 1013. As each of the plurality of sensor modules 100 do not include satellite or 4G communications capabilities, they are not equipped to communicate externally to the mesh network. As such, gateway node 1010 acts as a gateway router for such external communication each of the plurality of sensor modules 100.

It will be appreciated that whilst each of the plurality of sensor modules 100 in FIG. 10 are each identical, in other embodiments, each of sensor modules 100 may be different in terms of their respective physical sensor units 104. For example, some of sensor modules 100 may only include a weather station, some only a LiDAR sensor, some with both weather station and LiDAR sensors, etc. System 100 functions in the same manner irrespective of the types of sensors within each sensor module 100.

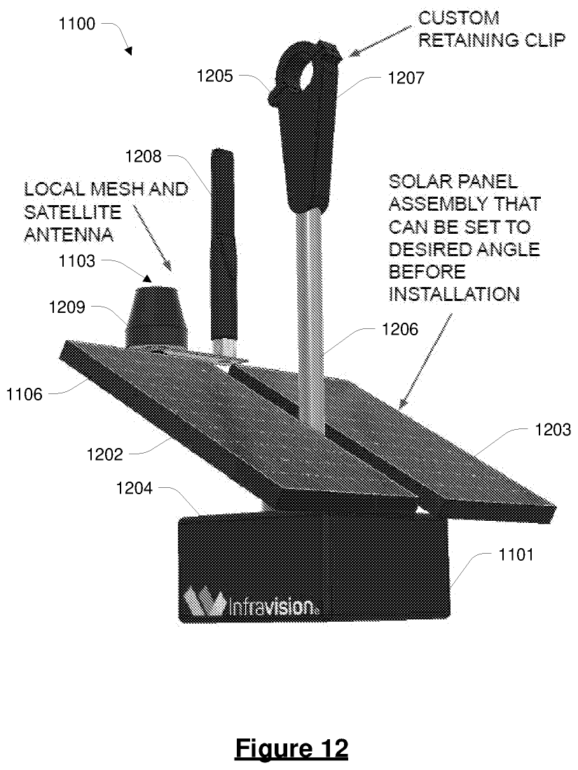

Referring to FIG. 11, there is illustrated a preferred embodiment of a gateway node 1100 equivalent to gateway node 1010 of FIG. 10. Gateway node 1100 includes a gateway housing 1101 including a mounting means adapted to mount gateway node 1100 to an earth power line wire. Gateway node 1100 includes a processing unit in the form of a gateway microprocessor 1102 housed within housing 1101 and also coupled to a gateway communications unit 1103 also housed within housing 101 for facilitating external communication. Microprocessor 1102 takes the form of a STM32H7 processor.

Gateway node 1100 includes a gateway power supply 1104 coupled to microprocessor 1102 and gateway communications unit 1103 for supplying power to microprocessor 1102 and gateway communications unit 1103. Power supply 1104 includes a rechargeable battery in the form of a lithium-ion battery assembly 1105 mounted within housing 1101 and a solar panel assembly 1106 mounted externally on housing 1101. It will be appreciated that solar panel assembly 1106 is used to re-charge battery assembly 1105. Battery assembly 1105 includes: a battery 1113; a first DC-DC converter 1114 upstream of battery 1113 and downstream of solar panel assembly 1106; and a second DC-DC converter 1115 downstream of battery 1113. It will be appreciated that power supply 1104 is such that solar panel assembly 1106 and battery assembly 1105 are able to power microprocessor 1102 and gateway communications unit 1103 in varying weather conditions, that is, in weather conditions that are not conducive to providing great amounts of solar energy and therefore solar panel assembly 1106 cannot be heavily relied upon for providing power.

Housing 1101 is formed from a rigid weather-proof plastic polymer that is configured to house at least some of the electronic components of gateway node 1100 in order to protect those components from weather such as precipitation and dust. In some embodiments, housing 1101 is completely waterproof. Housing 1101 is preferably of a size and material as small and light as practical to contain and support the relevant components of senor module 100 so as not to impact the dynamic response or add overdue fatigue to the earth wire upon which sensor module 100 is mounted. The specific physical form of housing 1101 will vary in various embodiments, a number of which will be described further below.

Communications unit 1103 includes a mesh network comms unit 1120 (such as a DigiMesh unit or the like) to create a mesh network where mesh network comms unit 1120 communicates either directly or indirectly with multiple sensor modules 100 within that mesh network (collectively illustrated in FIG. 11 as reference 1121). Communications unit 1103 also includes a satellite comms module in the form of a Swarm module 1122 and a LTE comms module 1123 providing respective satellite and 4G communications capabilities for facilitating digital communications to an external server via the cloud. More specifically, communications unit 1103 enables microprocessor 1102 to provide a communication gateway between multiple sensor modules 100 via the mesh network to the cloud via a communications arrangement such as a communications satellite 1124 and/or 4G communications infrastructure in the form of an LTE tower 1125.

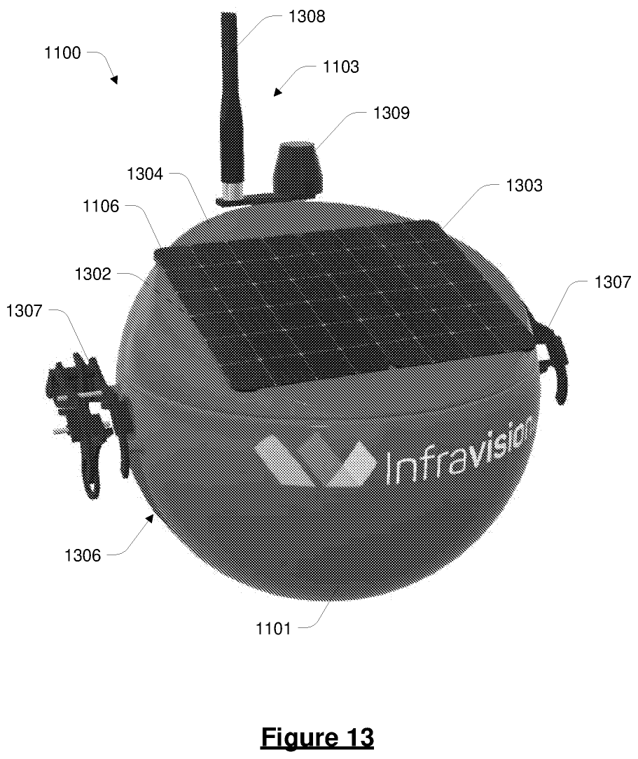

Referring to FIG. 12, there is illustrated an embodiment of gateway node 1100. Housing 1101 takes the form of a rectangular prism. Solar panel assembly 1106 includes a pair of solar panels 1202 and 1203 mounted on a top surface 1204 of housing 1101 by way of a bracket (not shown). Further, gateway node 1100 includes a mounting means 1205 that includes a vertically mounted shaft 1206 mounted at one end to top surface 1204 and at the other end to a clamping mechanism in the form of a retaining clip 1207 that is adapted to attach to an earth wire. Communications unit 1103 includes a mesh network antenna 1208 and a satellite antenna 1209. It will be appreciated that this embodiment of gateway node 1100 will be mounted to the earth wire in the same fashion as the embodiments of sensor module 100 from FIGS. 2, 4, 6, and 8.

Referring to FIG. 13, there is illustrated an embodiment of gateway node 1100 where housing 1101 takes the form of a power line marker ball. Solar panel assembly 1106 includes a pair of solar panels 1302 and 1303 mounted on a top surface 1304 of housing 1101. Further, the mounting means includes a groove formation 1306 and a pair of clamping mechanisms in the form of a pair of retaining clips 1307 disposed on opposing sides of housing 1101 at opposite ends of formation 1306 such that formation 1306 is configured to receive the earth wire when gateway node 1100 is positioned and dropped on the earth wire and clips 1307 are each adapted to attach to the earth wire. Communications unit 1103 includes a mesh network antenna 1308 and a satellite antenna 1309. It will be appreciated that this embodiment of gateway node 1100 will be mounted to the earth wire in the same fashion as the embodiment of sensor module 100 from FIGS. 7A and 7B.

It will be appreciated that the embodiment of sensor module 100 in FIG. 4 also has gateway node functionality (noting it includes satellite antenna 408) and therefore does not require a gateway node to communicate with the cloud.

It will be appreciated that the embodiment of sensor module 100 in FIG. 8 has cloud communication functionality (noting it includes satellite antenna 808) and does not therefore require a gateway node to communicate with the cloud. It will further be appreciated that the embodiment of sensor module 100 in FIG. 8 does not include a mesh network antenna and therefore is not part of any mesh network, essentially functioning as a standalone sensor module 100 node that can communicate with the cloud. Therefore, the embodiment of sensor module 100 in FIG. 8 includes both the functionality of sensor module 100 and gateway node 1100 in the one device. It will be appreciated that in other embodiments, the functionality of sensor module 100 in FIG. 8 will have the form of housing 101 of sensor module 100 in FIGS. 7A and 7B.

In order to measure line sag following the UAV mounting sensor module 100 on the earth wire, microprocessor 103 instructs LiDAR sensor 123 to initiates measurement scans. The raw data measurement taken is transmitted via the mesh network to a gateway node 1100 servicing the mesh network and microprocessor 1102 computes a sag result and uploads it to a cloud server database via the communications arrangement (4G or satellite). In other embodiments, the sag result is computed by microprocessor 103. In yet other embodiments, the sag result is computed at the server. The server, running bespoke software, consumes the sag result from the cloud server database to produce a real-time DLR. The DLR is the able to be transmitted to the relevant third part, such as the relevant Energy Market Operator.

In order to measure line distance to an object such as vegetation, following the UAV mounting sensor module 100 on the earth wire, similar to measuring line sag, microprocessor 103 instructs LiDAR sensor 123 to initiate measurement scans, and LiDAR sensor 123 pulses at a certain predefined frequency which, in a preferred embodiment, is 10 kHz or thereabouts. In other embodiments, the predefined frequency is more or less than 10 kHz. LiDAR sensor 123 is slewed (preferably using a gimbal) to collect distance data for a slice of space that is scanned. The collect distance data for the slice is filtered by microprocessor 103 to reduce the quantity of distance data. Then, for each measured distances from the reduced quantity of data, an IMU reading of roll, pitch and yaw is matched by microprocessor 103 to the data via a timestamp on each piece of raw data. The roll, pitch and yaw data is combined by microprocessor 103 with the corresponding distance reading to produce a 3D point of each shot. From here, microprocessor 103 discards any 3D point that is out of a specified 3D region of interest so the number of total points is less than 300 points. The remaining 3D points are transmitted by the mesh network to gateway node 1100 where microprocessor 1102 combines the latest 3D data points with historical model data. Microprocessor 1102 locates the conductor with the specified 3D region of interest and then the distance is calculated from the located conductor to the ground, which is identified using a 1 metre by 1 metre 2D ground plane. Microprocessor 1102 then computes the line clearance distance based on the ground to conductor distance and then uploads this data to the cloud server database.

Further, clearance distance data timestamped and combined with weather station data can be used to show the movement response of lines under certain weather conditions. Thus, based on weather forecasts, a forecast of potential movement of a line can be deduced.

As noted in this embodiment, the 3D slice is transmitted to gateway node 1100 to calculate distance. However, in other embodiments, the final distance calculations done at gateway node 1100 are calculated the sensor module 100 by microprocessor 103 and the resultant distance is transmitted to gateway node 1100 via the mesh network.

It will be appreciated that the onboard microprocessors (microprocessor 103 and microprocessor 1102) are able to process the raw 3D point cloud data captured by LiDAR sensor 123 through onboard processing driven by the above described proprietary algorithm specifically designed to compress the large volume of raw data to efficiently transmissible data packets.

In respect of measurements from weather station 122, it will be appreciated that such measurements are transmitted by microprocessor in regular 15 minute intervals. In other embodiments, such measurement are transmitted in other than 15 minute intervals.

### Advantages of Detailed Embodiments

It will be appreciated that the embodiments of sensor module 100 and the associated system 1000 described herein are advantageous over known devices and systems as they provide an efficient and accurate means to obtain sensory data relating to a conductor wire. The sensor module itself includes the following advantageous features:
The use of infrared to measure conductor temperature only requires a relatively small solar power supply and provides a low-cost component that can also be installed at a low cost.
The use of LiDAR to measure line sag and clearance to objects also only requires a relatively small solar power supply and provides a low-cost component that can also be installed at a low cost. This allows units to be placed at multiple locations.
The use of LiDAR, gyroscope, accelerometer and GPS to measure line movement provides a low-cost component that can also be installed at a low cost.
The integrated weather station provides accurate and repeatable measurements at low cost.
The ability to be mounted at any desired critical point on the earth wire, for example the lowest sag point and/or a point closest to a known object/vegetation, such that measurements taken will be at the point on the earth wire that is closest to the ground or object.
Weather resistant housing.
In embodiments where the housing resembles a marker ball, utilisation of an existing required component (the marker ball) with the additional sensory capabilities.
As earth wires are disposed above the active wires on standard power line arrangements, the position of the sensor module will be better placed to provide more accurate weather detection, for example truer wind velocity readings, (due to the greater height and less object interference as compared to mounting on the lower active wires) and ease of installation using the UAV.
Sensor modules can be customised differently in terms of what sensors are included based on bespoke requirements. In other words, if a unit only requires LiDAR, then a module could be constructed (at lower cost) without a weather station.
Modules mounted on the earth wire, not an active wire, thus being able to be mounted at any time without the need to disrupt power supply.
The microprocessor on sensor modules are able to filter out noise through on board processing, and convert the raw data to efficiently transmissible data.

The system including the sensor module includes the following advantageous features:
Both sensor modules and gateway nodes in the system can be installed in the exact same fashion via a UAV on the earth wire.
Use of a UAV for installing sensor modules and gateway nodes provides a much safer process to any manual installation.
Measurement of temperature in real-time of the nearest conductor which can be used to determine the real-time capacity of the conductor line.
Temperature measurements can be used to confirm the accuracy of existing models.
Real-time sensor measurements are provided or where this is not possible, sensor measurements provided at regular intervals to provide superior monitoring.
This solution allows bundling of messages, thereby reducing satellite transmission data costs.
Hardware costs are also reduced through use of mesh network, lessening the amount of more costly satellite/LTE components.

These features allow the systems and device herein to provide accurate sensory measurements, and easy and safe installation without the need for any electricity supply downtime, thereby eliminating all the issues with the traditional methods discussed in the background section.

### CONCLUSIONS AND INTERPRETATION

Throughout this specification, where used, the term “element” is intended to mean either a single unitary component or a collection of components that combine to perform a specific function or purpose.

It should be appreciated that in the above description of exemplary embodiments of the invention, various features of the invention are sometimes grouped together in a single embodiment, Figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those skilled in the art. For example, in the following claims, any of the claimed embodiments can be used in any combination.

Similarly, it is to be noticed that the term coupled, when used in the claims, should not be interpreted as being limited to direct connections only. The terms “coupled” and “connected,” along with their derivatives, may be used. It should be understood that these terms are not intended as synonyms for each other. Thus, the scope of the expression a device A coupled to a device B should not be limited to devices or systems wherein an output of device A is directly connected to an input of device B. It means that there exists a path between an output of A and an input of B which may be a path including other devices or means. “Coupled” may mean that two or more elements are either in direct physical, electrical or optical contact, or that two or more elements are not in direct contact with each other but yet still co-operate or interact with each other.

Unless specifically stated otherwise, as apparent from the following discussions, it is appreciated that throughout the specification discussions utilizing terms such as “processing,” “computing,” “calculating,” “determining”, analysing” or the like, refer to the action and/or processes of a computer or computing system, or similar electronic computing device, that manipulate and/or transform data represented as physical, such as electronic, quantities into other data similarly represented as physical quantities.

In a similar manner, the term “processor” may refer to any device or portion of a device that processes electronic data, e.g., from registers and/or memory to transform that electronic data into other electronic data that, e.g., may be stored in registers and/or memory. A “computer” or a “computing machine” or a “computing platform” may include one or more processors.

Some methodologies or portions of methodologies described herein are, in one embodiment, performable by one or more processors that accept computer-readable (also called machine-readable) code containing a set of instructions that when executed by one or more of the processors carry out at least one of the methods described herein. A memory subsystem of a processing system includes a computer-readable carrier medium that carries computer-readable code (e.g., software) including a set of instructions to cause performing, when executed by one or more processors, one of more of the methods described herein. Note that when the method includes several elements, e.g., several steps, no ordering of such elements is implied, unless specifically stated. The software may reside in the storage medium, or may also reside, completely or at least partially, within the RAM and/or within the processor during execution thereof by the computer system. Thus, the memory and the processor also constitute computer-readable carrier medium carrying computer-readable code.

Furthermore, a computer-readable carrier medium may form, or be included in a computer program product.

In alternative embodiments, unless otherwise specified, the one or more processors operate as a standalone device or may be connected, e.g., networked to other processor(s), in a networked deployment, the one or more processors may operate in the capacity of a server or a user machine in server-user network environment, or as a peer machine in a peer-to-peer or distributed network environment. The one or more processors may form a personal computer (PC), a tablet PC, a set-top box (STB), a Personal Digital Assistant (PDA), a cellular telephone, a web appliance, a network router, switch or bridge, or any machine capable of executing a set of instructions (sequential or otherwise) that specify actions to be taken by that machine.

Note that while only a single processor and a single memory that carries the computer-readable code may be shown herein, those in the art will understand that many of the components described above are included, but not explicitly shown or described in order not to obscure the inventive aspect. For example, while only a single machine is illustrated, the term “machine” shall also be taken to include any collection of machines that individually or jointly execute a set (or multiple sets) of instructions to perform any one or more of the methodologies discussed herein, unless otherwise specified.

Thus, one embodiment of each of the methods described herein is in the form of a computer-readable carrier medium carrying a set of instructions, e.g., a computer program that is for execution on one or more processors, e.g., one or more processors that are part of web server arrangement. Thus, as will be appreciated by those skilled in the art, embodiments of the present invention may be embodied as a method, an apparatus such as a special purpose apparatus, an apparatus such as a data processing system, or a computer-readable carrier medium, e.g., a computer program product. The computer-readable carrier medium carries computer readable code including a set of instructions that when executed on one or more processors cause the processor or processors to implement a method. Accordingly, aspects of the present invention may take the form of a method, an entirely hardware embodiment, an entirely software embodiment or an embodiment combining software and hardware aspects. Furthermore, the present invention may take the form of carrier medium (e.g., a computer program product on a computer-readable storage medium) carrying computer-readable program code embodied in the medium.

The software may further be transmitted or received over a network via a network interface device. While the carrier medium may be shown in an embodiment to be a single medium, the term “carrier medium” should be taken to include a single medium or multiple media (for example, a centralized or distributed database, and/or associated caches and servers) that store the one or more sets of instructions. The term “carrier medium” shall also be taken to include any medium that is capable of storing, encoding or carrying a set of instructions for execution by one or more of the processors and that cause the one or more processors to perform any one or more of the methodologies of the present invention. A carrier medium may take many forms, including but not limited to, non-volatile media, volatile media, and transmission media. Non-volatile media includes, for example, optical, magnetic disks, and magneto-optical disks. Volatile media includes dynamic memory, such as main memory. Transmission media includes coaxial cables, copper wire and fibre optics, including the wires that comprise a bus subsystem. Transmission media also may also take the form of acoustic or light waves, such as those generated during radio wave and infrared data communications. For example, the term “carrier medium” shall accordingly be taken to included, but not be limited to, solid-state memories, a computer product embodied in optical and magnetic media; a medium bearing a propagated signal detectable by at least one processor of one or more processors and representing a set of instructions that, when executed, implement a method; and a transmission medium in a network bearing a propagated signal detectable by at least one processor of the one or more processors and representing the set of instructions.

It will be understood that the steps of methods discussed are performed in one embodiment by an appropriate processor (or processors) of a processing (i.e., computer) system executing instructions (computer-readable code) stored in storage.

1. A non-live wire mounted sensor module including:
a housing including a mounting means adapted to mount the module to a non-live power line wire;
a power supply;
a physical sensor unit supported by the housing, wherein the physical sensor unit includes at least one of the group including:
a conductor temperature sensor;
a weather station;
a line sag detection sensor;
an object proximity sensor; and
a line movement sensor; and
a communications unit housed within the housing for facilitating external communication of output of the at least one physical sensor unit.

2. The sensor module according to claim 1 wherein the physical sensor unit includes a plurality of the group including:
the conductor temperature sensor;
the weather station;
the line sag detection sensor;
the object proximity sensor; and
the line movement sensor.

3. The sensor module according to claim 1 wherein the power supply includes a solar panel mounted externally on the housing.

4. The sensor module according to claim 1 wherein the power supply includes at least one battery disposed within the housing.

5. The sensor module according to claim 4 wherein the at least one battery is rechargeable.

6. The sensor module according to claim 1 wherein the weather station includes one or more of: a temperature sensor; a solar radiation sensor; a wind speed sensor; and a wind direction sensor.

7. The sensor module according to claim 1 wherein the conductor temperature sensor includes an infrared sensor.

8. The sensor module according to claim 1 wherein the line sag detection sensor includes a LiDAR sensor.

9. The sensor module according to claim 1 wherein the object proximity sensor includes a LiDAR sensor.

10. The sensor module according to claim 1 wherein the line movement sensor includes one or more of: a gyroscope; an accelerometer; a global positioning system (GPS) sensor; and a LiDAR sensor.

11. The sensor module according to claim 1 wherein the physical sensor unit includes an integrated sensor including the functionality of both the line sag detection sensor and the object proximity sensor.

12. The sensor module according to claim 1 wherein the physical sensor unit is mounted externally to the housing.

13. The sensor module according to claim 1 wherein the physical sensor unit is mounted within the housing.

14. The sensor module according to claim 1 wherein the physical sensor unit is mounted both externally and within the housing.

15. The sensor module according to claim 1 wherein the mounting means includes at least one clamp mechanism.

16. The sensor module according to claim 15 wherein the mounting means includes a pair of clamp mechanisms.

17. The sensor module according to claim 15 wherein the clamp mechanism includes a raptor clamp.

18. A method for mounting a sensor module on a non-live power line wire using an unmanned aerial vehicle (UAV), the method including the steps of:
providing a non-live wire mounted sensor module of any one of the preceding claims;
releasably attaching the sensor module to the UAV;
from a launch point, controlling the UAV to move it to a sensor release point such that the mounting means is positioned for mounting to the non-live wire;
controlling the to initiate mounting to the non-live wire; and
controlling the UAV to release the sensor module once mounted to the non-live wire.

19. A system for sensing one or more physical measurements, the system including:
at least one non-live wire mounted sensor module of claim 1;
a communications arrangement for facilitating digital communications with a server; and
a communications gateway node for facilitating digital communications between the at least one sensor module and the communications arrangement.

20. A system according to claim 19 wherein the system for sensing one or more physical measurements includes a plurality of sensor modules and the respective communications units of the plurality of sensor modules create a mesh network for communicating the plurality of sensor modules with the communications gateway node.
